(19) United States
(12) Patent Application Publication
(10) Pub. No.: US 2025/0187638 A1
(43) Pub. Date: Jun. 12, 2025

(54) TRANSPORT VEHICLE AND TRANSPORT SYSTEM INCLUDING THE SAME

(71) Applicant: SEMES CO., LTD., Chungcheongnam-do (KR)

(72) Inventors: Sik KIM, Gyeonggi-do (KR); Jun Beom LEE, Gyeonggi-do (KR)

(21) Appl. No.: 18/977,896

(22) Filed: Dec. 11, 2024

(30) Foreign Application Priority Data
Dec. 12, 2023 (KR) 10-2023-0179367

(51) Int. Cl. B61L 27/04

(52) U.S. Cl. CPC B61L 27/04

(57) ABSTRACT

Provided is a transport system for compensating for a distance difference caused by a slip phenomenon between a driving wheel and a rail when a plurality of transport vehicles performing a platoon driving simultaneously start. The transport system includes: a first transport vehicle moving along a rail and including a first motion controller and a first driver for rotating a first driving wheel; a second transport vehicle moving in a platoon driving with the first transport vehicle along the rail and including a second motion controller and a second driver for rotating a second driving wheel; and an upper controller controlling the first transport vehicle and the second transport vehicle, wherein the upper controller provides a transport command to the first transport vehicle and the second transport vehicle, depending on the transport command, the first motion controller provides a first position command to the first driver, and the second motion controller provides a second position command to the second driver, and when a first interval between the first transport vehicle and the second transport vehicle becomes wider than a first reference, the first motion controller provides the first driver with a third position command that indicates a position closer than the first position command, and the second transport vehicle provides the second driver with a fourth position command that indicates a position closer than the second position command.

### CROSS-REFERENCE TO RELATED APPLICATION

This application claims priority from Korean Patent Application No. 10-2023-0179367 filed on Dec. 12, 2023 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a transport vehicle and a transport system including the same.

### 2. Description of the Related Art

In a process of manufacturing semiconductor devices, substrates may be transported via an unmanned transport system. In particular, the unmanned transport system may include a transport vehicle (e.g., an overhead hoist transport (OHT), a rail guided vehicle (RGV), etc.) configured to be movable along a running rail installed on the ceiling or floor of a clean room. The operation control of the transport vehicle may be controlled by an upper controller such as an OHT control server (OCS) device.

### SUMMARY

Aspects of the present disclosure provide a transport system for compensating for a distance difference caused by a slip phenomenon between the driving wheels and the rail when a plurality of transport vehicles that perform platoon driving simultaneously start.

Aspects of the present disclosure also provide a transport vehicle for compensating for a distance difference caused by a slip phenomenon between the driving wheels and the rail when a plurality of transport vehicles that perform platoon driving simultaneously start.

Aspects of the present disclosure are not limited to the aspects mentioned above, and other aspects not mentioned will be clearly understood by those skilled in the art from the following description.

According to an aspect of the present disclosure, there is provided a transport system including: a first transport vehicle moving along a rail and including a first motion controller and a first driver for rotating a first driving wheel; a second transport vehicle moving in a platoon driving with the first transport vehicle along the rail and including a second motion controller and a second driver for rotating a second driving wheel; and an upper controller controlling the first transport vehicle and the second transport vehicle, wherein the upper controller provides a transport command to the first transport vehicle and the second transport vehicle, depending on the transport command, the first motion controller provides a first position command to the first driver, and the second motion controller provides a second position command to the second driver, and when a first interval between the first transport vehicle and the second transport vehicle becomes wider than a first reference, the first motion controller provides the first driver with a third position command that indicates a position closer than the first position command, and the second transport vehicle provides the second driver with a fourth position command that indicates a position closer than the second position command.

According to another aspect of the present disclosure, there is provided a transport system including: a memory configured to store a reference acceleration; a motion controller configured to generate a position command based on the reference acceleration; a driver configured to receive the position command and rotate a driving wheel; and a communicator configured to communicate with fellow transport vehicles belonging to a platoon driving group, wherein the motion controller includes: generating a position command based on the reference acceleration and providing the position command to the driver, receiving an interval between the fellow transport vehicles through the communicator, decreasing the reference acceleration, when the interval becomes wider than the first reference, and generating a position command based on the decreased reference acceleration and providing the position command to the driver.

According to still another aspect of the present disclosure, there is provided a transport system including: a memory configured to store a reference acceleration; a motion controller configured to generate a position command based on the reference acceleration; a driver configured to receive the position command and rotate a driving wheel; a communicator configured to communicate with fellow transport vehicles belonging to a platoon driving group; and a distance sensor configured to measure an interval with the fellow transport vehicle positioned directly in front, wherein the motion controller includes generating a position command based on the reference acceleration and providing the position command to the driver, the communicator includes transmitting the interval measured by the distance sensor to a master transport vehicle, the communicator includes receiving a command to adjust the reference acceleration from the master transport vehicle, the motion controller includes adjusting the reference acceleration, and the motion controller includes generating a position command based on the adjusted reference acceleration and providing the position command to the driver.

The details of other exemplary embodiments are included in the detailed description and drawings.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a conceptual diagram for describing a transport system according to some exemplary embodiments of the present disclosure;

FIG. 2 is a diagram for describing a transport vehicle illustrated in FIG. 1;

FIG. 3 is a conceptual diagram for describing an operation of the transport system according to some exemplary embodiments of the present disclosure;

FIG. 4 is a conceptual diagram for describing an operation of the transport system according to some exemplary embodiments of the present disclosure;

FIG. 5 is a block diagram for describing transport vehicles illustrated in the transport system of FIG. 3;

FIG. 6 is a block diagram for describing a motion controller of FIG. 5;

FIG. 7 is a flowchart for describing a method for operating a transport system according to some exemplary embodiments of the present disclosure;

FIG. 8 is a diagram for describing an operation of the transport system according to some exemplary embodiments of the present disclosure;

FIG. 9 is a diagram for describing an operation of the transport system according to some exemplary embodiments of the present disclosure;

FIG. 10 is a diagram for describing an operation of the transport system according to some exemplary embodiments of the present disclosure; and

FIG. 11 is a diagram for describing an operation of the transport system according to some exemplary embodiments of the present disclosure.

### DETAILED DESCRIPTION OF THE EMBODIMENTS

Hereinafter, embodiments of the present disclosure will be described in detail with reference to the accompanying drawings. Advantages and features of the present disclosure, and a method for achieving the advantages and features will become apparent with reference to the exemplary embodiments described below in detail in conjunction with the accompanying drawings. However, the present disclosure is not limited to the exemplary embodiments disclosed below, but may be implemented in a variety of different forms, these exemplary embodiments will be provided only in order to make the present disclosure complete and allow those skilled in the art to completely recognize the scope of the present disclosure, and the present disclosure is only defined by the scope of the claims. The same reference numbers indicate the same components throughout the specification.

Spatially relative terms “below”, “beneath”, “lower”, “above”, “upper”, and the like, may be used to easily describe correlations between one element or components and another element or components as illustrated in the drawings. The spatially relative terms are to be understood as terms including different directions of the elements at the time of use or operation in addition to directions illustrated in the drawings. For example, when an element illustrated in the drawing is turned over, an element described as being ‘below or beneath’ another element may be located ‘above’ another element. Therefore, an exemplary term ‘below’ may include both of directions of below and above. The element may also be oriented in other orientations, and thus spatially relative terms may be interpreted according to the orientation.

Terms “first”, “second” and the like are used to describe various elements, components, and/or sections but these elements, components, and/or sections are not limited by these terms. These terms are used only in order to distinguish one element, component, or section from another element, component or section. Accordingly, a first element, a first component, or a first section mentioned below may also be a second element, a second component, or a second section within the spirit of the present disclosure.

Hereinafter, exemplary embodiments of the present disclosure will be described in detail with reference to the accompanying drawings. In describing the exemplary embodiments of the present disclosure with reference to the accompanying drawings, components that are the same as or correspond to each other will be denoted by the same reference numerals, and an overlapping description thereof will be omitted.

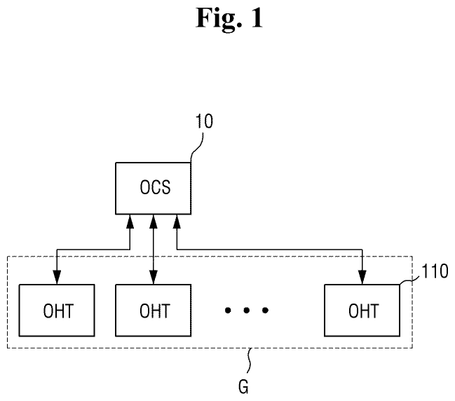

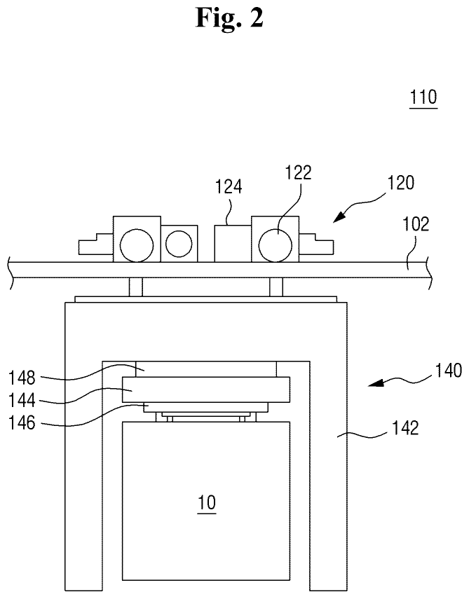

FIG. 1 is a conceptual diagram for describing a transport system according to some exemplary embodiments of the present disclosure. FIG. 2 is a diagram for describing a transport vehicle illustrated in FIG. 1.

First, referring to FIG. 1, a transport system according to some exemplary embodiments of the present disclosure includes an upper controller (OHT control system (OCS)) 10 and a plurality of transport vehicles 110.

The transport vehicle 110 may be an overhead hoist transport (OHT) that runs along a rail installed on the ceiling or floor of a semiconductor manufacturing plant (i.e., FAB), but is not limited thereto. The transport vehicle 110 may be an automated guided vehicle (AGV) or autonomous mobile robots (AMR) installed on the floor rather than on the rail.

The upper controller 10 communicates with the plurality of transport vehicles 110, for example, through wireless communication, and controls the plurality of transport vehicles 110. The upper controller 10 provides a transport command to each transport vehicle 110. The transport command may include information such as a starting position (node A), a destination position (node B), and a load (transport item). The transport command may include a platoon driving command in which the plurality of transport vehicles form a platoon driving group G to transport the load, or a single driving command in which one transport vehicle transports the load alone.

Here, referring to FIG. 2, the transport vehicle 110 may transport a container 10, such as a Front Opening Unified Pod (FOUP), that stores wafers while moving along a rail 102 within the semiconductor manufacturing plant.

Such a transport vehicle 110 includes a housing 142, a driving module 120, and a hoist module 140.

The driving module 120 is installed on the housing 142 and is installed to be movable along the rail 102. The driving module 120 includes a driving wheel 122 and a motor 124 for rotating the driving wheel 122. In this specification, “driving wheel” means at least one of a front driving wheel and a rear driving wheel, and “motor” means at least one of a front motor driving the front driving wheel and a rear motor driving the rear driving wheel.

The hoist module 140 is installed in an internal space of the housing 142 and rises and falls while gripping the container 10.

The hoist module 140 may include a hoist unit 144 for raising and lowering the container 10, a slide unit 148 for moving the hoist unit 144 in the left and right directions, and a hand unit 146 connected to the hoist unit 144 and for holding the container 10.

Referring again to FIG. 1, the upper controller 10 may provide the platoon driving command to the plurality of transport vehicles 110. That is, the upper controller 10 may instruct the plurality of transport vehicles 110 to form a single platoon driving group G and transport the assigned loads from the starting position to the destination.

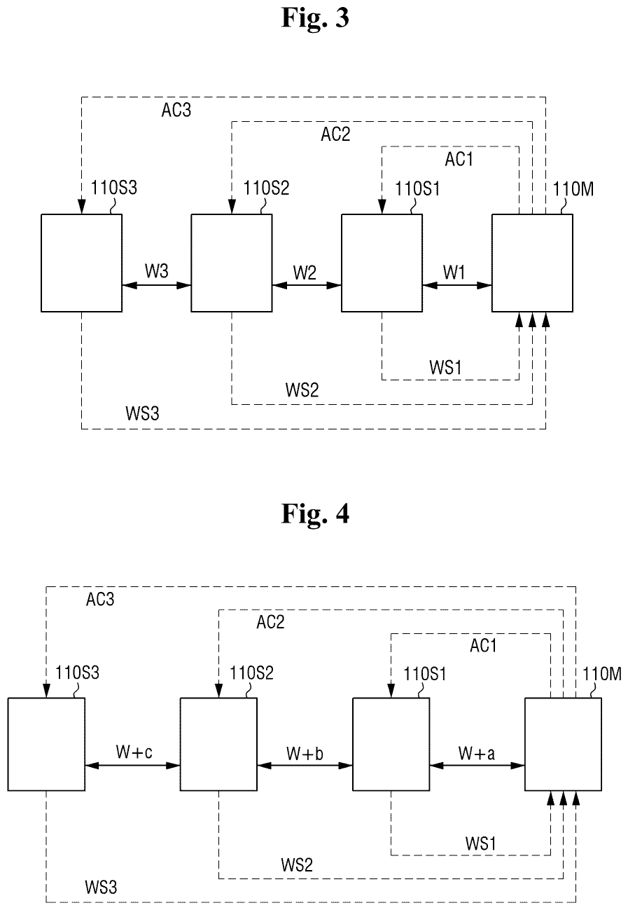

FIGS. 3 and 4 are conceptual diagrams for describing an operation of the transport system according to some exemplary embodiments of the present disclosure;

First, referring to FIG. 3, the transport system may include a plurality of transport vehicles 110M, 110S1, 110S2, and 110S3 forming one platoon driving group G.

One of the plurality of transport vehicles 110M, 110S1, 110S2, and 110S3 may be a master transport vehicle 110M and the rest may be fellow transport vehicles 110S1, 110S2, and 110S3. It is illustrated in the drawing that the frontmost transport vehicle in the platoon driving group G is the master transport vehicle 110M, but the present disclosure is not limited thereto. For example, the last transport vehicle in the platoon driving group G may also be the master transport vehicle 110M.

When the plurality of transport vehicles 110M, 110S1, 110S2, and 110S3 move while forming the platoon driving group G, an interval between the transport vehicles 110M, 110S1, 110S2, and 110S3 adjacent to each other needs to be maintained to be substantially constant. For example, the fellow transport vehicle 110S1 measures an interval W1 from the master transport vehicle 110M positioned directly in front of the fellow transport vehicle 110S1, the fellow transport vehicle 110S2 measures an interval W2 from the fellow transport vehicle 110S1 positioned directly in front of the fellow transport vehicle 110S2, and the fellow transport vehicle 110S3 measures an interval W3 from the fellow transport vehicle 110S2 positioned directly in front of the fellow transport vehicle 110S3.

Each of the plurality of fellow transport vehicles 110S1, 110S2, and 110S3 provides the master transport vehicle 110M with interval information WS1, WS2, and WS3 corresponding to the measured intervals W1, W2, and W3.

The master transport vehicle 110M reviews the provided interval information WS1, WS2, and WS3 and determines whether to adjust reference acceleration. For example, the master transport vehicle 110M may determine whether to adjust the reference acceleration by calculating an average value of the intervals W1, W2, and W3 and then comparing the average value with a preset reference. Alternatively, the master transport vehicle 110M may also compare each of the intervals W1, W2, and W3 with the preset reference. Alternatively, at least two of a reference compared with the interval W1, a reference compared with the interval W2, and a reference compared with the interval W3 may be different from each other.

The master transport vehicle 110M may provide commands AC1, AC2, and AC3 to adjust the reference acceleration based on the review results.

Each of the transport vehicles 110M, 110S1, 110S2, and 110S3 generates a position command based on the reference acceleration, and controls a rotation speed of the driving wheel through position/speed/current control according to the position command. Here, initial reference acceleration is set by considering various factors such as the performance of a motor for rotating the driving wheel. Since the position command is generated based on the reference acceleration, the position command may indicate a relatively distant position when the reference acceleration is high, and the position command may indicate a relatively close position when the reference acceleration is low. Therefore, the position command may be adjusted by adjusting the reference acceleration.

Sometimes, the intervals W1, W2, and W3 may increase between the plurality of transport vehicles 110M, 110S1, 110S2, and 110S3 forming the platoon driving group G. For example, when the plurality of transport vehicles 110M, 110S1, 110S2, and 110S3 simultaneously start accelerating at the start of platoon driving, slip may occur between the driving wheel and the rail, which may increase the intervals W1, W2, and W3 between the plurality of transport vehicles 110M, 110S1, 110S2, and 110S3.

As illustrated in FIG. 4, before acceleration, the intervals W1, W2, and W3 between the plurality of transport vehicles 110M, 110S1, 110S2, and 110S3 are W, but after acceleration, the intervals W1, W2, and W3 between the plurality of transport vehicles 110M, 110S1, 110S2, and 110S3 may increase (see, e.g., W+a, W+b, and W+c).

In this case, according to the transport system according to some exemplary embodiments of the present disclosure, the master transport vehicle 110M may receive interval information WS1, WS2, and WS3 related to the intervals W+a, W+b, and W+c from the fellow transport vehicles 110S1, 110S2, and 110S3, and may provide commands AC1, AC2, and AC3 to decrease the reference acceleration to the fellow transport vehicles 110S1, 110S2, and 110S3. The master transport vehicle 110M also decreases the reference acceleration.

In this way, the plurality of transport vehicles 110M, 110S1, 110S2, and 110S3 generate position commands indicating positions closer than before. As a result, actual acceleration of the plurality of transport vehicles 110M, 110S1, 110S2, and 110S3 is reduced, and the intervals W1, W2, and W3 between the plurality of transport vehicles 110M, 110S1, 110S2, and 110S3 are reduced.

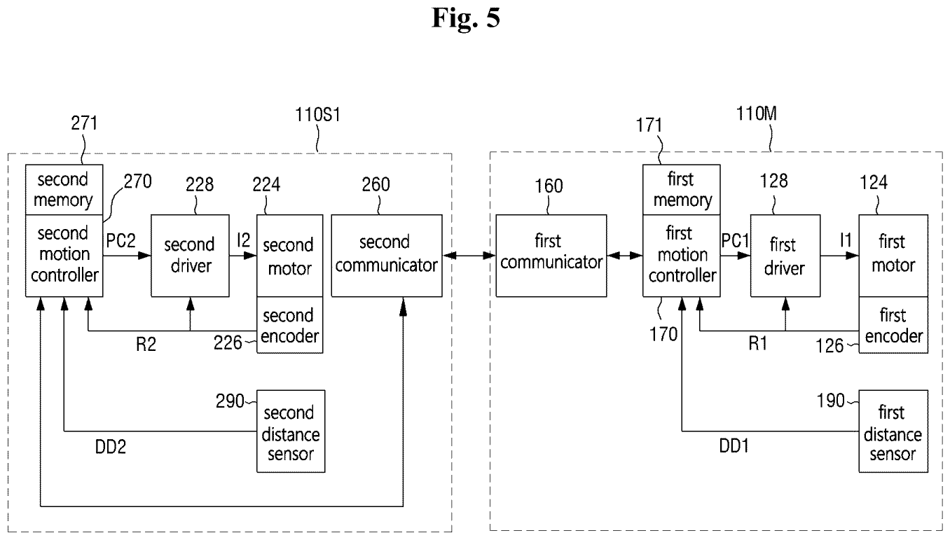

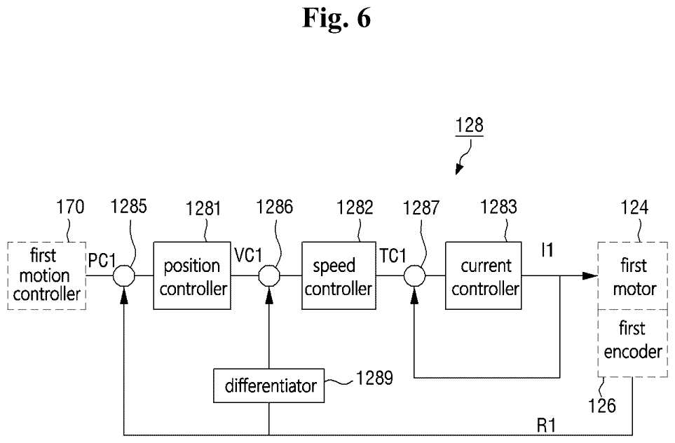

FIG. 5 is a block diagram for describing transport vehicles illustrated in the transport system of FIG. 3. FIG. 6 is a block diagram for describing a motion controller of FIG. 5.

First, referring to FIG. 5, the master transport vehicle 110M includes a first motion controller 170, a first memory 171, a first driver 128, a first motor 124, a first encoder 126, a first communicator 160, and a first distance sensor 190.

The first motion controller 170 may provide a position command PC1 to the first driver 128 at preset times (or according to a cycle) based on the transport command provided from the upper controller (see 10 in FIG. 1).

As described above, the transport command includes the information such as the starting position, the destination position, and the load. The position command PC1 is generated based on the transport command and indicates an intermediate path position to reach the destination. That is, the position command PC1 may indicate how far the transport vehicle needs to move per preset time (e.g., 1 msec) to reach the destination. For example, if the transport command indicates that the transport vehicle needs to start at position 1 and move to position 30, the position command PC1 may indicate that the transport vehicle needs to move to position 5 within a preset time.

In addition, the first motion controller 170 performs position planning in advance based on the reference acceleration. In the above example, the first motion controller 170 may plan that the transport vehicle needs to move to positions 5, 10, 15, 20, 25, and 30 at preset times. If the master transport vehicle 110M moves according to the plan, the first motion controller 170 sequentially generates position commands PC1 corresponding to the positions 5, 10, 15, 20, 25, and 30 at preset times.

However, the position planning is modified considering a current position of the master transport vehicle 110M. For example, if the master transport vehicle 110M fails to move to position 5 within the preset time and only moves to position 4, the plan may be modified so that the transport vehicle needs to move in the following order: positions 4, 9, 14, 19, 24, 29, and 30 at preset times.

Meanwhile, if the reference acceleration decreases, a distance the transport vehicle may move within the preset time decreases. In this case, the first motion controller 170 may plan that the transport vehicle needs to move to positions 3, 6, 9, 12, 15, 18, 21, 24, 27, and 30 at preset times.

The reference acceleration is stored in the first memory 171. The first motion controller 170 may adjust the reference acceleration. That is, the first motion controller 170 may increase or decrease the reference acceleration.

The first driver 128 generates a first current I1 for controlling the first motor 124 connected to the first driving wheel based on the position command PC1.

The first motor 124 is connected to the driving wheel and adjusts an angular speed of the driving wheel as the rotational speed changes depending on the size of the current I1 provided from the first driver 128.

The first encoder 126 measures the rotational speed of the first motor 124. The measurement result (i.e., the encoder signal R1) is provided to the first motion controller 170 and the first driver 128. The first motion controller 170 and the first driver 128 may check the position of the master transport vehicle 110M based on the encoder signal R1.

The first communicator 160 may include a plurality of communication modules for communicating with a plurality of objects. For example, the first communicator 160 may include a communication module for communicating with the upper controller OCS, a communication module for organizing an internal status of the master transport vehicle 110M and reporting it to a diagnostic server, and a communication module for communicating with other transport vehicles (e.g., transport vehicles belonging to the platoon driving group). Hereinafter, a communication method for communicating with adjacent vehicles is called vehicle to vehicle communication. Through the vehicle to vehicle communication, communication with a second communicator 260 of the fellow transport vehicle 110S1 may be performed.

The first distance sensor 190 measures a distance to the transport vehicle positioned in front and reports a measured distance DD1 to the first motion controller 170. The type of the first distance sensor 190 may vary and may include, for example, an ultrasonic sensor, an infrared sensor, a LIDAR sensor, a radar sensor, a camera sensor, etc.

The fellow transport vehicle 110S1 includes a second motion controller 270, a second memory 271, a second driver 228, a second motor 224, a second encoder 226, a second communicator 260, and a second distance sensor 290.

The fellow transport vehicle 110S1 and master transport vehicle 110M are substantially identical in structure and operating principles. The second motion controller 270 may provide a position command PC2 to the second driver 228 at preset times (or according to a cycle) based on the transport command provided from the upper controller (see 10 in FIG. 1). The reference acceleration is stored in the second memory 271. The second motion controller 270 may increase or decrease the store reference acceleration. The second driver 228 generates a second current I2 for controlling the second motor 224 connected to the second driving wheel based on the position command PC2. The second motor 224 is connected to the driving wheel and adjusts an angular speed of the driving wheel as the rotational speed changes depending on the size of the second current I2 provided from the second driver 228. The second encoder 226 measures the rotational speed of the second motor 224. The measurement result (i.e., the encoder signal R2) is provided to the second motion controller 270 and the second driver 228. The second communicator 260 includes a plurality of communication modules for communicating with a plurality of objects (an upper controller, a diagnostic server, other transport vehicles, etc.). The second distance sensor 290 measures a distance to the transport vehicle positioned in front and reports a measured distance DD2 to the second motion controller 270.

Hereinafter, the first driver 128 will be described with reference to FIG. 6.

The first driver 128 includes a position controller 1281, a speed controller 1282, and a current controller 1283 and may be controlled in a feedback manner.

Specifically, a calculator 1285 receives the position command PC1 provided from the first motion controller 170 and the encoder signal R1 provided from the first encoder 126, and calculates a difference therebetween.

The position controller 1281 generates a speed command VC1 corresponding to an output of the calculator 1285. That is, the position controller 1281 may detect whether the position of the master carriage 110M detected by the encoder signal R1 is an appropriate position when compared with the position command PC1. That is, when reviewing the result calculated by the calculator 1285, if the position of the master transport vehicle 110M is at the appropriate position, the position controller 1281 maintains the speed of the master transport vehicle 110M as it is. On the other hand, if the position of the master transport vehicle 110M does not reach the position specified in the position command PC1, the position controller 1281 increases the speed of the master transport vehicle 110M. Conversely, if the position of the master transport vehicle 110M passes the position specified in the position command PC1, the position controller 1281 needs to decrease the speed of the master transport vehicle 110M.

A differentiator 1289 differentiates the encoder signal R1 provided from the encoder 126 and provides the result to a calculator 1286. The calculator 1286 receives the speed command VC1 and the result value of the differentiator 1289 and calculates a difference therebetween.

The speed controller 1282 generates a current command TC1 corresponding to an output of the calculator 1286. If the speed of the master transport vehicle 110M needs to be increased, the angular acceleration of the driving wheel needs to be increased, so that the current command TC1 is changed accordingly. Conversely, if the speed of the master transport vehicle 110M needs to be decreased, the angular acceleration of the driving wheel needs to be decreased, so that the current command TC1 is changed accordingly.

A calculator 1287 receives the current command TC1 and the first current I1 and calculates a difference therebetween.

The current controller 1283 generates a first current I1 corresponding to an output of the calculator 1287.

The first motor 124 is operated by the first current I1 and rotates the driving wheel connected to the first motor 124.

Although not described separately, the second driver 228 is also substantially identical to the first driver 128.

Here, referring again to FIG. 5, the master transport vehicle 110M and fellow transport vehicles 110S1 belonging to the platoon driving group receive a transport command from the upper controller 10.

According to the transport command, the first motion controller 170 provides a first position command to the first driver 128, and the second motion controller 270 provides a second position command to the second driver 228. The first motion controller 170 generates a first position command based on the first reference acceleration stored in the first memory 171. The second motion controller 270 generates a second position command based on the second reference acceleration stored in the second memory 271. The first reference acceleration and the second reference acceleration may be preset values by considering the performance of the first motor 124 and the second motor 224, respectively. The first reference acceleration and the second reference acceleration may be equal to each other.

The second distance sensor 290 measures an interval between the master transport vehicle 110M and the fellow transport vehicle 110S1. The second communicator 260 transmits interval information corresponding to the measured interval (see WS1 in FIG. 1) to the first communicator 160. The first motion controller 170 checks whether the interval W1 between the master transport vehicle 110M and the fellow transport vehicle 110S1 is wider than a first reference based on the interval information WS1.

If the first motion controller 170 determines that the interval W1 is wider than the first reference, the first motion controller 170 generates a third position command that indicates a position closer than the first position command and provides the third position command to the first driver 128. The second motion controller 270 generates a fourth position command that indicates a position closer than the second position command and provides the fourth position command to the second driver 228.

Specifically, the first motion controller 170 determines whether to change the reference acceleration based on the interval information WS1.

If it is determined that the interval W1 is wider than the first reference, the first motion controller 170 changes the first reference acceleration stored in the first memory 171 to third reference acceleration that is smaller than the first reference acceleration. In addition, the first motion controller 170 generates a third position command based on the third reference acceleration.

In addition, the first motion controller 170 transmits a command to decrease the reference acceleration to the second communicator 260 through the first communicator 160.

The second motion controller 270 changes the second reference acceleration stored in the second memory 271 to fourth reference acceleration that is smaller than the second reference acceleration according to the command. In addition, the second motion controller 270 generates a fourth position command based on the fourth reference acceleration.

Here, the third reference acceleration and the fourth reference acceleration may be equal to each other.

In this way, when the interval between the master transport vehicle 110M and the fellow transport vehicle 110S1 increases, the speed of the master transport vehicle 110M and the fellow transport vehicle 110S1 may be slowed down by decreasing the reference acceleration.

For example, a slip may occur in the fellow transport vehicle 110S1, which may cause the interval between the master transport vehicle 110M and the fellow transport vehicle 110S1 to increase. In this case, if the fellow transport vehicle 110S1 is indiscriminately accelerated through feedback control of the second driver 228 to narrow the interval, the slip phenomenon may more occur. In addition, by continuously increasing the second current I2 to accelerate, the battery consumption or power consumption may become very severe.

On the other hand, according to the transport system according to some exemplary embodiments of the present disclosure, both the master transport vehicle 110M and the fellow transport vehicle 110S1 generate a position command indicating a close position by decreasing the reference acceleration, and accordingly, a distance that both the master transport vehicle 110M and the fellow transport vehicle 110S1 need to move is reduced. Therefore, the master transport vehicle 110M and the fellow transport vehicle 110S1 may slowly escape a section where the slip phenomenon occurs.

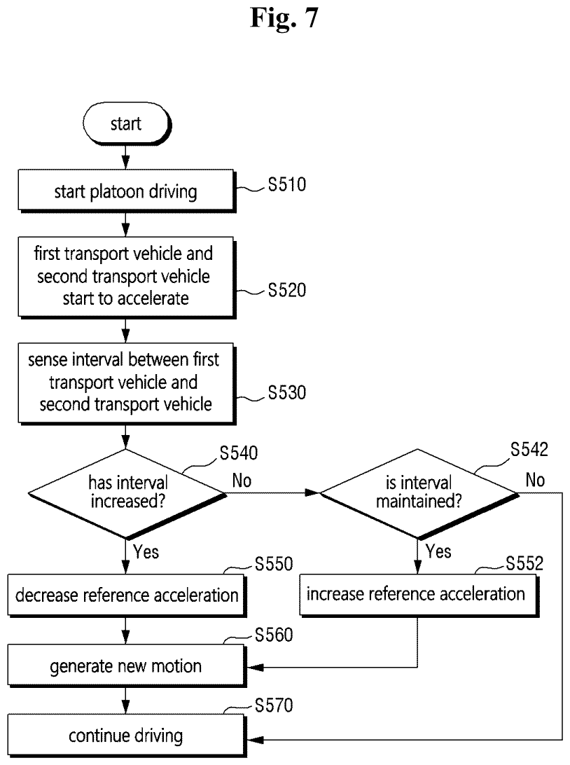

FIG. 7 is a flowchart for describing a method for operating a transport system according to some exemplary embodiments of the present disclosure. Hereinafter, for convenience of explanation, the descriptions using FIGS. 3 to 6 will be omitted.

Referring to FIG. 7, upon receiving a transport command from the upper controller 10, a first transport vehicle and a second transport vehicle start (S510). Hereinafter, the first transport vehicle corresponds to the master transport vehicle, and the second transport vehicle corresponds to the fellow transport vehicle positioned immediately behind the master transport vehicle. The master transport vehicle or fellow transport vehicle may be determined by the upper controller 10. Alternatively, the master transport vehicle or fellow transport vehicle may be determined based on the transport vehicle's ID number. For example, the transport vehicle with the fastest ID number may be determined as the master transport vehicle. Alternatively, the transport vehicle at the front or back of the platoon driving group may be determined as the master transport vehicle.

Next, the first transport vehicle and the second transport vehicle start to accelerate (S520). As described above, the first transport vehicle generates the first position command based on the preset reference acceleration, and the second transport vehicle generates a second position command based on the preset reference acceleration.

Next, an interval between the first transport vehicle and the second transport vehicle is sensed (S530). For example, the interval may be sensed by sensing a distance between the second transport vehicle and the first transport vehicle directly in front of the second transport vehicle. The sensed interval is transmitted to the first transport vehicle.

Next, a first motion controller of the first transport vehicle checks whether the interval increases (S540).

For example, a slip may occur in the second transport vehicle. Accordingly, if the interval increases and exceeds the first reference (see Yes in S540), a reference acceleration of the first transport vehicle is decreased, and a reference acceleration of the second transport vehicle is decreased (S550). The first and second transport vehicles generate new position commands based on the decreased reference acceleration. That is, a new motion is generated (S560). The first transport vehicle generates a third position command based on the decreased reference acceleration, and the second transport vehicle generates a fourth position command based on the decreased reference acceleration.

If the interval has not increased (see No in S540), it is checked whether the interval is maintained constant (see S542).

If the interval is maintained (see Yes in S542), the reference acceleration of the first transport vehicle is increased, and the reference acceleration of the second transport vehicle is increased (S552). The first and second transport vehicles generate new position commands based on the increased reference acceleration. That is, a new motion is generated (S560).

For example, if the interval is maintained after the interval becomes wider than the first reference, the first transport vehicle generates a seventh position command that indicates a position closer than the third position command based on the increased reference acceleration, and the second transport vehicle generates an eighth position command that indicates a position closer than the fourth position command based on the increased reference acceleration.

If the interval is not maintained (see No in S542), driving continues without changing the reference acceleration (S570).

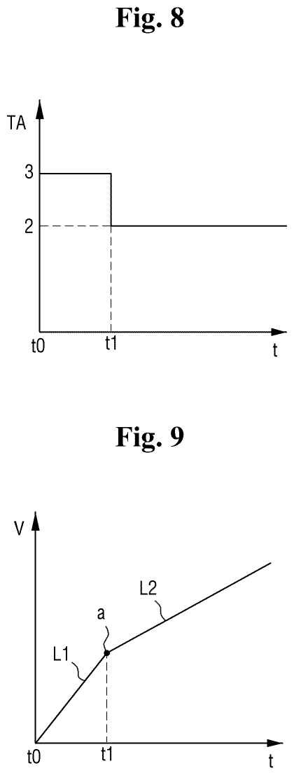

FIGS. 8 and 9 are diagrams for describing an operation of the transport system according to some exemplary embodiments of the present disclosure. For convenience of explanation, the description of the same as that described using FIGS. 3 to 7 will be omitted.

In FIG. 8, an x-axis represents time and a y-axis represents a reference acceleration. In FIG. 9, an x-axis represents time and a y-axis represents a speed of the second transport vehicle. The second transport vehicle may be a fellow transport vehicle that follows immediately behind the first transport vehicle (master transport vehicle).

Referring to FIGS. 8 and 9, at time to, the first transport vehicle and the second transport vehicle start a platoon driving. The second transport vehicle begins to increase in speed. From time t0 to time t1, the reference acceleration may be, for example, 3 m/s². A slope of a line segment L1 from time t0 to time t1 represents an actual acceleration of the second transport vehicle.

Although the speed of the second transport vehicle is illustrated as the line segment L1 for the convenience of the illustration, the speed of the second transport vehicle may actually have a sinuous shape because the speed of the second transport vehicle is controlled by feedback control.

At time t1, it may be determined that a slip has occurred in the second transport vehicle. For example, it is determined that the interval between the first and second transport vehicles is wider than the first reference. If it is determined that the slip has occurred, the reference acceleration may be decreased. After time t1, the reference acceleration may be, for example, 2 m/s². A slope of a line segment L2 after time t1 represents an actual acceleration of the second transport vehicle.

It may be seen that the slope of the line segment L2 is smaller than the slope of the line segment L1 centered on a point a.

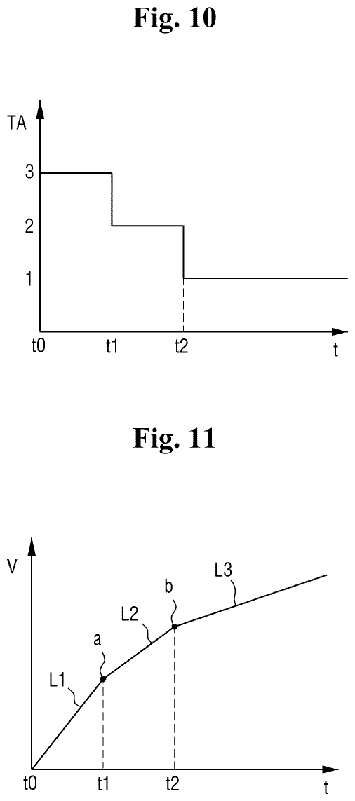

FIGS. 10 and 11 are diagrams for describing an operation of the transport system according to some exemplary embodiments of the present disclosure. For convenience of explanation, the description of the same as that described using FIGS. 3 to 9 will be omitted.

In FIG. 10, an x-axis represents time and a y-axis represents a reference acceleration. In FIG. 11, an x-axis represents time and a y-axis represents a speed of the second transport vehicle. The second transport vehicle may be a fellow transport vehicle that follows immediately behind the first transport vehicle (master transport vehicle).

Referring to FIGS. 10 and 11, at time t0, the first transport vehicle and the second transport vehicle start a platoon driving. The second transport vehicle begins to increase in speed. From time t0 to time t1, the reference acceleration may be, for example, 3 m/s².

At time t1, it may be determined that a slip has occurred in the second transport vehicle. For example, it is determined that the interval between the first and second transport vehicles is wider than the first reference. If it is determined that the slip has occurred, the reference acceleration may be decreased. After time t1, the reference acceleration may be, for example, 2 m/s².

Meanwhile, it may be determined that an additional slip has occurred in the second transport vehicle at time t2, even though the reference acceleration was decreased. For example, it may be determined that the interval between the first and second transport vehicles is wider than the second reference greater than the first reference. If it is determined that the slip has occurred, the reference acceleration may be additionally decreased. After time t1, the reference acceleration may be, for example, 1 m/s².

Here, a slope of a line segment L1 from time t0 to time t1, a slope of a line segment L2 from time t1 to time t2, and a slope of a line segment L3 after time t2 represent an actual acceleration of the second transport vehicle.

It may be seen that the slope of the line segment L2 is smaller than the slope of the line segment L1 centered on a point a. In addition, it may be seen that the slope of the line segment L3 is smaller than the slope of the line segment L2 centered on a point b.

For example, the first transport vehicle generates a first position command based on the first reference acceleration, and the second transport vehicle generates a second position command based on the second reference acceleration.

However, if the slip has occurred, the first reference acceleration is decreased to the third reference acceleration, and the second reference acceleration is decreased to the fourth reference acceleration. Therefore, the first transport vehicle (i.e., the first motion controller) generates a third position command that indicates a position closer than the first position command, and the second transport vehicle (i.e., the second motion controller) generates a fourth position command that indicates a position closer than the second position command.

If the slip has additionally occurred, the third reference acceleration is decreased to a fifth reference acceleration, and the fourth reference acceleration is decreased to a sixth reference acceleration. Therefore, the first transport vehicle (i.e., the first motion controller) generates a fifth position command that indicates a position closer than the third position command, and the second transport vehicle (i.e., the second motion controller) generates a sixth position command that indicates a position closer than the fourth position command.

Thereafter, if the interval between the first transport vehicle and the second transport vehicle becomes wider than a third reference that is greater than the second reference, the first transport vehicle and the second transport vehicle may stop. That is, the first transport vehicle (i.e., the first motion controller) receives interval information from the second transport vehicle and analyzes the interval information. As a result of the analysis, if it is determined that the interval has become too wide, the first motion controller may no longer perform reference acceleration control and may generate a command to stop the first and second transport vehicles.

Although the exemplary embodiments of the present disclosure have been described with reference to the accompanying drawings, those of ordinary skill in the art to which the present disclosure pertains will understand that the present disclosure may be embodied in other specific forms without changing the technical spirit or essential features thereof. Therefore, it should be understood that the exemplary embodiments described above are illustrative in all aspects and not restrictive.

What is claimed is:

1. A transport system comprising:
a first transport vehicle moving along a rail and including a first motion controller and a first driver for rotating a first driving wheel;
a second transport vehicle moving in a platoon driving with the first transport vehicle along the rail and including a second motion controller and a second driver for rotating a second driving wheel; and
an upper controller controlling the first transport vehicle and the second transport vehicle,
wherein the upper controller is configured to provide a transport command to the first transport vehicle and the second transport vehicle,
depending on the transport command, the first motion controller provides a first position command to the first driver, and the second motion controller provides a second position command to the second driver, and
when a first interval between the first transport vehicle and the second transport vehicle becomes wider than a first reference, the first motion controller provides the first driver with a third position command that indicates a position closer than the first position command, and the second transport vehicle provides the second driver with a fourth position command that indicates a position closer than the second position command.

2. The transport system of claim 1, wherein the first motion controller generates the first position command based on a first reference acceleration, and the second motion controller generates the second position command based on a second reference acceleration, and
when the first interval between the first transport vehicle and the second transport vehicle becomes wider than the first reference, the first motion controller generates the third position command based on a third reference acceleration that is smaller than the first reference acceleration, and the second motion controller generates the fourth position command based on a fourth reference acceleration that is smaller than the second reference acceleration.

3. The transport system of claim 2, wherein when the first interval between the first transport vehicle and the second transport vehicle becomes wider than the first reference, the first transport vehicle provides the second transport vehicle with a command instructing to decrease the second reference acceleration to the fourth reference acceleration.

4. The transport system of claim 2, wherein the second transport vehicle measures the first interval with the first transport vehicle positioned in front and providing the first interval to the first transport vehicle, and
the first transport vehicle determines whether to change the reference acceleration based on the provided first interval.

5. The transport system of claim 2, wherein the first reference acceleration and the second reference acceleration are the same, and the third reference acceleration and the fourth reference acceleration are the same.

6. The transport system of claim 2, wherein the first transport vehicle further includes a first memory, and when the first interval becomes wider than the first reference, the first reference acceleration stored in the first memory is changed to the third reference acceleration, and
the second transport vehicle further includes a second memory, and when the first interval becomes wider than the first reference, the second reference acceleration stored in the second memory is changed to the fourth reference acceleration.

7. The transport system of claim 1, wherein when the first interval between the first transport vehicle and the second transport vehicle becomes wider than a second reference greater than the first reference, the first motion controller provides the first driver with a fifth position command that indicates a position closer than the third position command, and the second transport vehicle provides the second driver with a sixth position command that indicates a position closer than the fourth position command.

8. The transport system of claim 7, wherein when the first interval between the first transport vehicle and the second transport vehicle becomes wider than a third reference greater than the second reference, the first transport vehicle and the second transport vehicle stop.

9. The transport system of claim 1, wherein when the first interval is maintained after becoming wider than the first reference, the first motion controller provides the first driver with a seventh position command that indicates a position closer than the third position command, and the second transport vehicle provides the second driver with an eighth position command that indicates a position closer than the fourth position command.

10. The transport system of claim 1, further comprising a third transport vehicle forming a platoon driving with the first transport vehicle and the second transport vehicle,
wherein the second transport vehicle measures the first interval with the first transport vehicle positioned directly in front of the second transport vehicle and provides the first interval to the first transport vehicle,
the third transport vehicle measures the second interval with the second transport vehicle positioned directly in front of the third transport vehicle and provides the second interval to the first transport vehicle,
the first transport vehicle determines whether to change the reference acceleration based on the first interval and the second interval, and
the first transport vehicle instructs the second transport vehicle and the third transport vehicle to change the reference acceleration.

11. The transport system of claim 1, wherein the interval between the first transport vehicle and the second transport vehicle becoming wider than the first reference includes a slip occurring in the second transport vehicle.

12. A transport vehicle comprising:
a memory configured to store a reference acceleration;
a motion controller configured to generate a position command based on the reference acceleration;
a driver configured to receive the position command and rotate a driving wheel; and
a communicator configured to communicate with fellow transport vehicles belonging to a platoon driving group,
wherein the motion controller includes:
generating a position command based on the reference acceleration and providing the position command to the driver,
receiving an interval between the fellow transport vehicles through the communicator,
decreasing the reference acceleration, when the interval becomes wider than the first reference, and
generating a position command based on the decreased reference acceleration and providing the position command to the driver.

13. The transport vehicle of claim 12, wherein the motion controller further includes:
additionally decreasing the reference acceleration, when the interval becomes wider than a second reference greater than the first reference after decreasing the reference acceleration, and
generating a position command based on the additionally decreased reference acceleration and providing the position command to the driver.

14. The transport vehicle of claim 12, wherein the motion controller further includes:
increasing the reference acceleration, when the interval is maintained after decreasing the reference acceleration, and
generating a position command based on the increased reference acceleration and providing the position command to the driver.

15. The transport vehicle of claim 12, wherein the motion controller transmits a command to decrease the reference acceleration to the fellow transport vehicles through the communicator, when the interval becomes wider than the first reference.

16. The transport vehicle of claim 12, wherein the interval becoming wider than the first reference includes a slip occurring in the fellow transport vehicles.

17. A transport vehicle comprising:
a memory configured to store a reference acceleration;
a motion controller configured to generate a position command based on the reference acceleration;
a driver configured to receive the position command and rotate a driving wheel;
a communicator configured to communicate with fellow transport vehicles belonging to a platoon driving group; and
a distance sensor configured to measure an interval with the fellow transport vehicle positioned directly in front,
wherein the motion controller includes generating a position command based on the reference acceleration and providing the position command to the driver,
the communicator includes transmitting the interval measured by the distance sensor to a master transport vehicle,
the communicator includes receiving a command to adjust the reference acceleration from the master transport vehicle,
the motion controller includes adjusting the reference acceleration, and
the motion controller includes generating a position command based on the adjusted reference acceleration and providing the position command to the driver.

18. The transport vehicle of claim 17, wherein when the interval becomes wider than a first reference, the motion controller includes decreasing the reference acceleration according to a command of the master transport vehicle.

19. The transport vehicle of claim 18, wherein when the interval becomes wider than a second reference greater than the first reference after decreasing the reference acceleration, the motion controller additionally decreases the reference acceleration according to the command of the master transport vehicle.

20. The transport vehicle of claim 18, wherein when the interval is maintained after decreasing the reference acceleration, the motion controller increases the reference acceleration according to the command of the master transport vehicle.
